(19) United States
(12) Patent Application Publication
(10) Pub. No.: US 2004/0217355 A1
(43) Pub. Date: Nov. 4, 2004

(54) Electroluminescent display device

(75) Inventor: Kiyoshi Yoneda, Mizuho-shi (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-city (JP)

(21) Appl. No.: 10/790,248

(22) Filed: Mar. 2, 2004

(30) Foreign Application Priority Data
Mar. 3, 2003 (JP) 2003-055336

(51) Int. Cl. H01L 29/04

(52) U.S. Cl. 257/72

(57) ABSTRACT

The invention prevents emitting of a bit of light from an organic EL element and affecting of a display. A gate insulating layer is formed extending on an active layer made of a polysilicon layer which is formed on a transparent insulating substrate made of a glass substrate. A gate extends over the gate insulating layer. An active layer is formed with a source/drain having an LDD structure. A source is formed of a P⁺ layer and a P⁻ layer which are in contact with each other. The P⁺ layer is a high concentration layer of boron as an impurity with concentration of about 1×10²⁰/cc. The P⁻ layer is a low concentration layer containing boron as an impurity with concentration of about 1×10¹⁸/cc, and formed extending in a direction between the P⁺ layer and the gate. A drain is also formed of a P⁺ layer and a P⁻ layer which are in contact with each other.

### BACKGROUND OF THE INVENTION

1. Field of the Invention

The invention relates to an electroluminescent display device, particularly having a pixel selecting transistor and a driving transistor for current-driving an electroluminescent element in a pixel.

2. Description of the Related Art

In recent years, an organic electroluminescent (hereafter, referred to as “EL”) display device using organic EL elements has been receiving attention as a new display device substituted for a CRT or an LCD. Particularly, an organic EL display device having thin film transistors (hereafter, referred to as TFTs) as switching elements for driving the organic EL elements is being developed.

FIG. 4 is an equivalent circuit diagram of one pixel in an organic EL display panel. In an actual organic EL display panel, a plurality of the pixels is disposed in a matrix of n rows and m columns. A gate signal line 10 for supplying a gate signal Gn and a drain signal line 11 for supplying a display signal Dm intersect each other.

An organic EL element 12, a driving TFT 13 for driving the organic EL element 12, and a pixel selecting TFT 14 for selecting a pixel are disposed on a periphery of an intersection of these signal lines.

A source 13s of the driving TFT 13 is supplied with positive power supply voltage PVdd from a power supply line 15. A drain 13d of the driving TFT 13 is connected with an anode of the organic EL element 12. A cathode of the organic EL element 12 is supplied with negative power supply voltage CV.

A gate of the pixel selecting TFT 14 is connected with the gate signal line 10, and supplied with the gate signal Gn. A drain 14d of the pixel selecting TFT 14 is connected with the drain signal line 11, and supplied with the display signal Dm. A source 14s of the pixel selecting TFT 14 is connected with a gate 13g of the driving TFT 13. The gate signal Gn is outputted from a vertical drive circuit (not shown). The display signal Dm is outputted from a horizontal drive circuit (not shown).

Furthermore, the gate 13g of the driving TFT 13 is connected with a storage capacitor Cs. The storage capacitor Cs stores the display signal Dm for the display pixel for a field period by storing electric charge corresponding to the display signal Dm.

Operation of the EL display device having the described structure will be described. When the gate signal Gn becomes high for a predetermined horizontal period, the pixel selecting TFT 14 turns on. Then, the display signal Dm is applied from the drain signal line 11 to the gate 13g of the driving TFT 13 through the pixel selecting TFT 14.

According to the display signal Dm supplied to the gate 13g, the conductance of the driving TFT 13 changes. A drive current corresponding to the changed conductance is supplied to the organic EL element 12 through the driving TFT 13, lighting the organic EL element 12. When the driving TFT 13 turns off according to the display signal Dm supplied to the gate 13g, an electric current is not supplied to the driving TFT 13, so that the organic EL element 12 also turns off the light.

Conventionally, the pixel selecting TFT 14 has been of N-channel type, and the driving TFT 13 has been of P-channel type. Such a structure is described, for example, in Japanese Patent Application Publication No. 2002-175029.

Conventionally, an LDD (lightly doped drain) structure has been employed for the pixel selecting TFT 14 in order to reduce leakage of an electric current for preventing fluctuation of a level of the gate 13g caused by the leaked electric current flowing in an off state. However, an ordinary source/drain structure with high impurity concentration has been employed for the driving TFT 13.

This results in a problem that a bit of drive current (leaked current) flows from the power supply line 15, and thus the organic EL element 12 emits a bit of light to affect a display, even when the driving TFT 13 is being set in an off state by gate voltage. The inventors found that this leaking current is generated between the gate 13g and the drain 13d, or the gate 13g and the source 13s.

### SUMMARY OF THE INVENTION

The invention provides an electroluminescent display device that includes a plurality of pixels, a pixel selecting transistor provided for each of the pixels, an electroluminescent element provided for each of the pixels, and a driving transistor provided for each of the pixels to drive a corresponding electroluminescent element according to a display signal supplied through a corresponding pixel selecting transistor. The driving transistor includes a channel of a P type and a lightly-doped-drain structure.

### BRIEF DESCRIPTION OF THE DRAWINGS

FIG. 1 is a pattern layout of an electroluminescent display device of an embodiment of the invention.

FIG. 2 is a cross-sectional view of a driving TFT of the embodiment of the invention.

FIG. 3 is another cross-sectional view of the driving TFT of the embodiment of the invention.

FIG. 4 is an equivalent circuit diagram of an electroluminescent display device of a conventional art.

### DESCRIPTION OF THE PREFERRED EMBODIMENTS

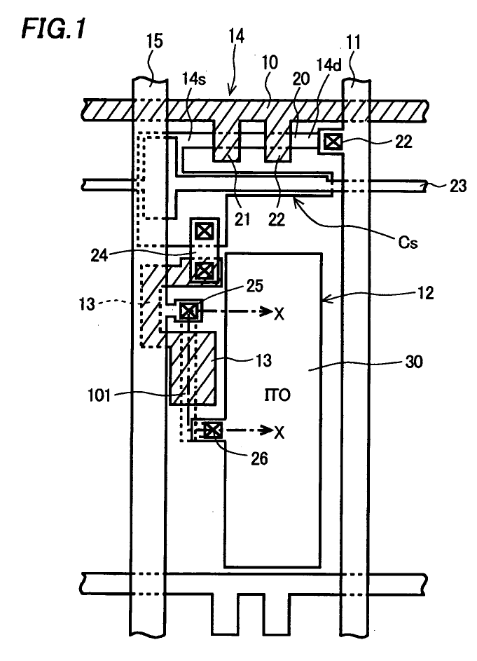

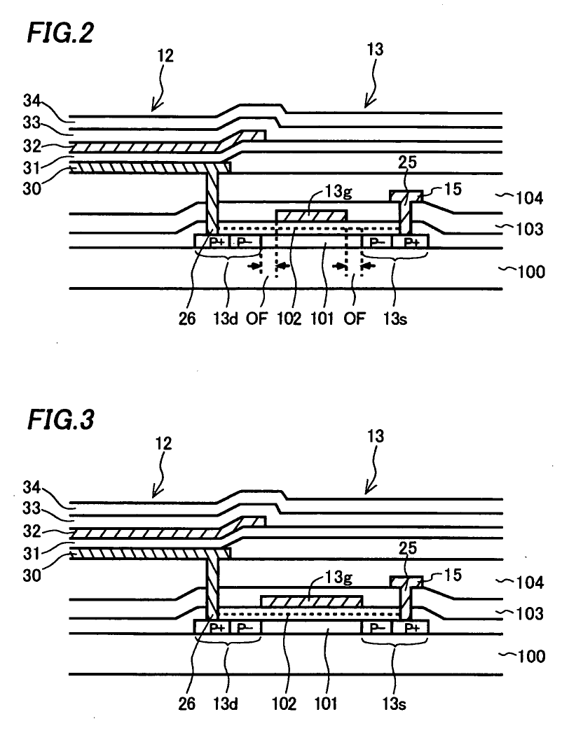

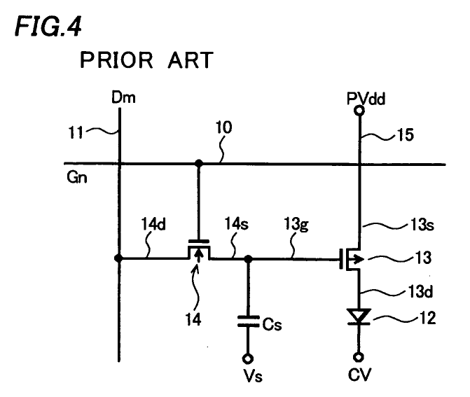

An organic EL display device of an embodiment of the invention will be described with reference to the drawings in detail. FIG. 1 shows an example of a pattern layout (plan view) of a pixel of the organic EL display device. FIGS. 2 and 3 are cross-sectional views along line X-X of FIG. 1. An equivalent circuit diagram of this organic EL display device is the same as FIG. 4. Structural components in FIG. 1 that correspond to those in FIG. 4 are assigned the same reference numerals.

A gate signal line 10 for supplying a gate signal Gn extends in a row direction, and a drain signal line 11 for supplying a display signal Dm extends in a column direction. These signal lines intersect each other. The gate signal line 10 is made of a Cr (chromium) layer or an Mo (molybdenum) layer. The drain signal line 11 is made of an Al (aluminum) layer, being formed above the gate signal line 10.

The pixel selecting TFT 14 is formed of a polysilicon TFT of N-channel type. The pixel selecting TFT 14 has a double gate structure, in which a gate insulating layer is formed on an active layer 20 made of a polysilicon layer which is formed on a transparent insulating substrate 100 made of a glass substrate, and two gates 21 and 22 extending from the gate signal line 10 are formed on the gate insulating layer.

A drain 14d of the pixel selecting TFT 14 is connected with the drain signal line 11 through a contact 22. A polysilicon layer forming a source 14s of the pixel selecting TFT 14 extends over a storage capacitor region, and a storage capacitor line 23 thereon overlaps the source 14s through a capacitor insulating film. This overlapping portion forms a storage capacitor Cs.

The polysilicon layer extending from the source 14s of the pixel selecting TFT 14 is connected with a gate 13g of a driving TFT 13 through Al wiring 24.

The driving TFT 13 is formed of a polysilicon TFT of P-channel type, having an LDD structure. The structure of the driving TFT 13 will be described with reference to FIGS. 2 and 3 in detail. First, the structure of the driving TFT 13 shown in FIG. 2 will be described.

A gate insulating layer 102 is formed on an active layer 101 made of a polysilicon layer which is formed on a transparent insulating substrate 100 made of a glass substrate. The gate insulating layer 102 is formed by laminating a silicon oxide film (SiO₂) and a silicon nitride film (SiNx) on the active layer 101 in this order. The silicon oxide film (SiO₂) has a thickness of 80 nm, and the silicon nitride film (SiNx) has a thickness of 40 nm, for example.

The gate 13g made of a Cr layer or an Mo layer extends on the gate insulating layer 102, and an interlayer insulating film 103 is formed over the gate 13g. Furthermore, a planarization insulating film 104 is formed on the interlayer insulating film 103.

A source and drain having the LDD structure is formed in the active layer 101. That is, a source 13s is formed of a P⁻ layer and a P⁺ layer which are in contact with each other. The P⁺ layer is a high concentration layer of an impurity, e.g. boron with concentration of about 1×10²⁰/cc . This P⁺ layer is connected with a power supply line 15, which is supplied with positive power supply voltage PVdd, through a contact hole 25 formed on the P⁺ layer. The P⁺ layer is in contact with a source electrode.

On the other hand, the P⁻ layer is a low concentration layer of an impurity, e.g. boron with concentration of about 1×10¹⁸/cc, and formed extending toward the gate 13g. The P⁻ layer is formed in a region keeping off from an edge of the gate 13g (by an offset length OF in FIG. 2). This offset region is an undoped region of an impurity. This can further reduce leakage of electric currents between the gate 13g and the source 13s.

The drain 13d is also formed of a P⁻ layer and a P⁺ layer which are in contact with each other. The P⁺ layer is a high concentration layer of an impurity, e.g. boron with concentration of about 1×10²⁰/cc, and connected with an anode 30 of the organic EL element 12 through a contact hole 26 formed on the P⁺ layer. The P⁺ layer is in contact with a drain electrode.

On the other hand, the P⁻ layer is a low concentration layer of an impurity, e.g. boron with concentration of about 1×10¹⁸/cc, and formed extending toward the gate 13g. The P⁻ layer is formed in a region keeping off from an edge of the gate 13g (by an offset length OF in FIG. 2) in a similar manner to the source 13s. This offset region is also an undoped region of an impurity. This can further reduce leakage of electric currents between the gate 13g and the drain 13d.

A hole transport layer 31, an emissive layer 32, and an electron transport layer 33 are laminated on the anode 30 of the organic EL element 12, and a cathode 34 is further formed thereon.

As described above, the driving TFT 13 shown in FIG. 2 has the LDD structure with the offset regions. On the other hand, the driving TFT 13 shown in FIG. 3 has no offset region. In such a driving TFT 13 having no offset region, the P⁻ layer is formed by self-alignment with the edges of the gate 13g by ion implantation.

What is claimed is:

1. An electroluminescent display device comprising:
a plurality of pixels;
a pixel selecting transistor provided for each of the pixels;
an electroluminescent element provided for each of the pixels; and
a driving transistor provided for each of the pixels to drive a corresponding electroluminescent element according to a display signal supplied through a corresponding pixel selecting transistor, the driving transistor comprising a channel of a Ptype and a lightly-doped-drain structure.

2. The electroluminescent display device of claim 1, wherein the driving transistor further comprises a gate electrode, a P-type impurity region and a region of no doped impurities that is disposed between the gate electrode and the P-type impurity region.

3. The electroluminescent display device of claim 1, wherein the driving transistor further comprises a high concentration region containing a P-type impurity with a concentration of 1×10²⁰/cc or more and being in contact with an electrode, and a low concentration region containing a P-type impurity with a concentration of 1×10¹⁸/cc or less and disposed between the high concentration region and the channel region.

4. The electroluminescent display device of claim 2, wherein the P-type impurity region comprises a high concentration region containing a P-type impurity with a concentration of 1×10²⁰/cc or more and being in contact with an electrode, and a low concentration region containing a P-type impurity with a concentration of 1×10¹⁸/cc or less and disposed between the high concentration region and the channel region.
